(19) United States
(12) Patent Application Publication
(10) Pub. No.: US 2009/0161887 A1
(43) Pub. Date: Jun. 25, 2009

(54) DATA PROCESSING APPARATUS AND METHOD OF CONTROLLING THE SAME

(75) Inventor: Makoto Yamaguchi, Sagamihara-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Kabushiki Kaisha Toshiba, Tokyo (JP)

(21) Appl. No.: 12/340,328

(22) Filed: Dec. 19, 2008

(30) Foreign Application Priority Data
Dec. 21, 2007 (JP) 2007-331053

(51) Int. Cl. H03G 5/00

(52) U.S. Cl. 381/98

(57) ABSTRACT

According to one embodiment, a data processing apparatus includes a control section which, when the performance of the memory device is at a predetermined threshold value or higher, stores the frequency while associating it to a volume of the sound generated and increase a frequency of sound generated next by a certain frequency band from the frequency, when the performance of the memory device is less than the predetermined threshold level, decreases the volume of the sound by a certain volume level from the maximum volume, when the volume corresponding to the highest frequency, which is the predetermined frequency, is stored, finishes the measurement, and generates the sound from the lowest frequency to the highest frequency from the loudspeaker in accordance with the volume stored and the frequency corresponding to the volume.

### CROSS-REFERENCE TO RELATED APPLICATIONS

This application is based upon and claims the benefit of priority from Japanese Patent Application No. 2007-331053, filed Dec. 21, 2007, the entire contents of which are incorporated herein by reference.

### BACKGROUND

1. Field

One embodiment of the present invention generally relates to a technique of controlling the loudness and frequency of audio sound generated by data processing apparatus, and more specifically to a data processing apparatus capable of controlling the loudness of audio sound at a certain frequency generated by itself, which adversely affecting a memory device, and a method of controlling the apparatus.

2. Description of the Related Art

Generally, in personal computers equipped with an integrated loudspeaker, the vibration generated from the speaker is propagated to an integrated hard disk drive, thereby causing an adverse effect on the performance of the hard disk drive in many cases. For example, Jpn. Pat. Appln. KOKAI Publication No. 8-106719 discloses a technique for an optical disk reproduction apparatus, which attenuates the volume of sound being generated when detecting an erroneous focus control or tracking control, thereby preventing a reproduction disable state caused by the vibration of the audio sound from continuing for a long time, and achieving stable audio sound reproduction.

However, the technique disclosed in Jpn. Pat. Appln. KOKAI Publication No. 8-106719 controls the loudness of audio sound by attenuating the volume itself, and therefore it creates a great adverse effect on the audibility when the user is listening to the sound.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary block diagram schematically showing an example of the structure of a data processing apparatus according to an embodiment of the present invention;

FIG. 2 is an exemplary block diagram schematically showing the configuration of the data processing apparatus according to the embodiment;

FIG. 3 is an exemplary functional block diagram showing the configuration of the control application according to the embodiment;

FIG. 4 is an exemplary flowchart illustrating the control method according to the embodiment;

FIG. 5 is an exemplary conceptual diagram of the case where the volume control is carried out at various frequencies by the data processing apparatus according to the embodiment; and

FIG. 6 is an exemplary conceptual diagram illustrating a conversion process in which the gain is controlled by the data processing apparatus according to the embodiment so as to carry out an unclipped output control.

### DETAILED DESCRIPTION

Various embodiments according to the invention will be described hereinafter with reference to the accompanying drawings. In general, according to one embodiment of the invention, a data processing apparatus equipped with a memory device and a loudspeaker, the apparatus includes: an audio output section which generates sound from the loudspeaker at a predetermined maximum volume and a predetermined lowest frequency; a measurement section which measures a performance of the memory device; and a control section which, when the performance of the memory device is at a predetermined threshold value or higher, stores the frequency while associating it to a volume of the sound generated and increase a frequency of sound generated next by a certain frequency band from the frequency, when the performance of the memory device is less than the predetermined threshold level, decreases the volume of the sound by a certain volume level from the maximum volume, when the volume corresponding to the highest frequency, which is the predetermined frequency, is stored, finishes the measurement, and generates the sound from the lowest frequency to the highest frequency from the loudspeaker in accordance with the volume stored and the frequency corresponding to the volume.

An embodiment of the present invention will now be described with reference to accompanying drawings.

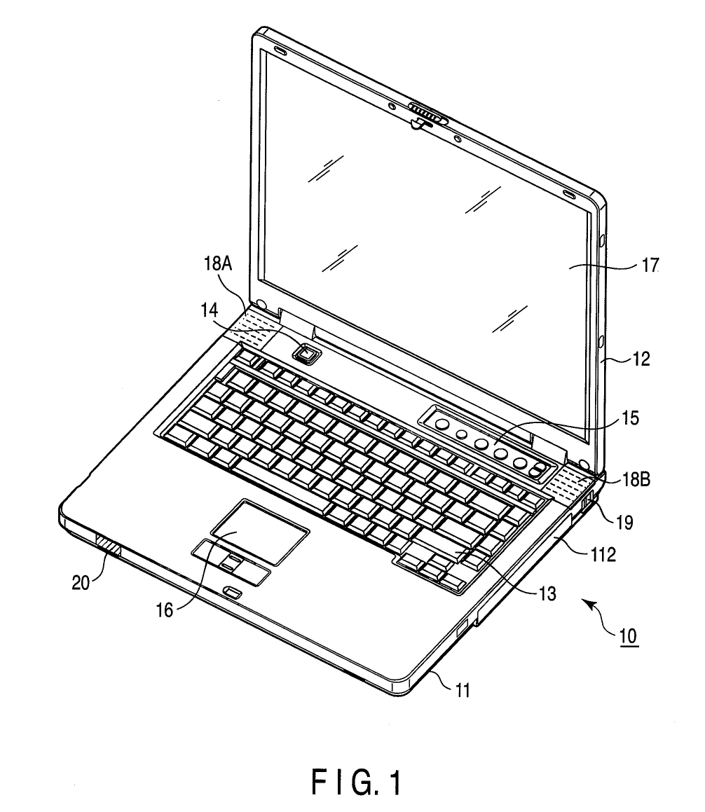

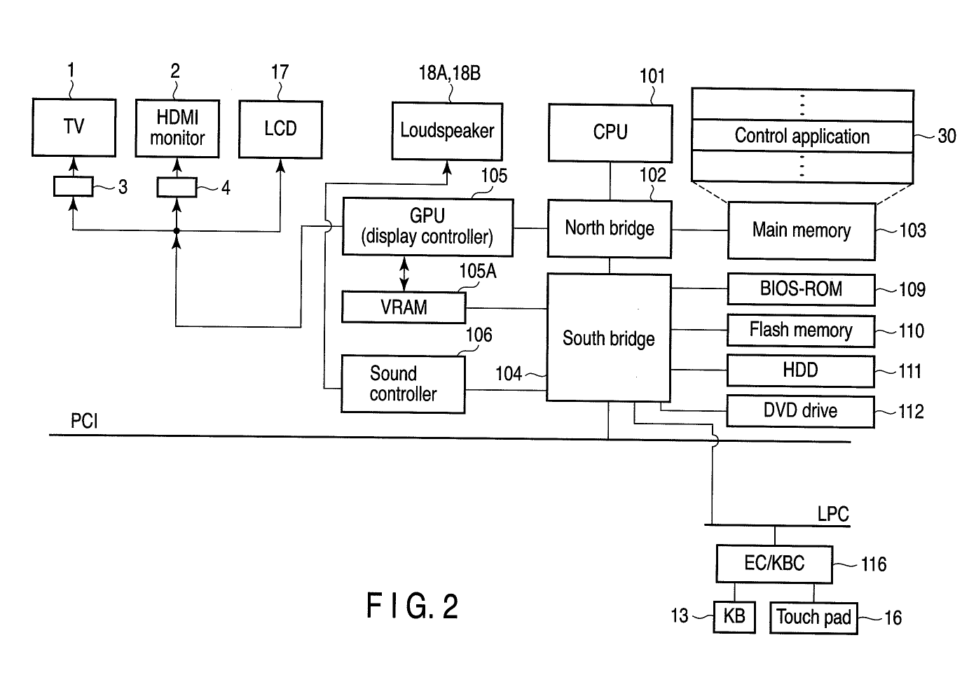

First, with reference to FIGS. 1 and 2, the configuration of a data processing apparatus according to an embodiment of the present invention will be described. This data processing apparatus is realized as, for example, a notebook personal computer 10.

FIG. 1 is a perspective view of the notebook personal computer 10 when the display unit is opened. The computer 10 includes a computer main body 11 and a display unit 12. The display unit 12 contains a built-in display device which is formed of a thin film transistor liquid crystal display (TFT-LCD) 17, and the display screen of the LCD 17 is located in substantially a central portion of the display unit 12.

The display unit 12 is mounted to the computer main body 11 pivotably between an open position and a close position. The computer main body 11 includes a thin box-shaped cabinet, on an upper surface of which a keyboard 13, a power button 14 which turns ON/OFF the computer 10, an operation panel 15, a touch pad 16, loudspeakers 18A and 18B, a DVD drive 112, an infrared receiving section 20, etc. are arranged.

The operation panel 15 is an entry device comprising a plurality of buttons which respectively start various functions, and it is used to enter an event corresponding to a button pressed by the user.

Next, with reference to FIG. 2, the system configuration of the computer 10 will be described.

As shown in FIG. 2, the computer 10 of this embodiment includes a CPU 101, a north bridge 102, a main memory 103, a south bridge 104, a GPU 105, a BIOS-ROM 109, a flash memory 110, a hard disk drive (HDD) 111, a DVD drive 112, an embedded controller/keyboard controller IC (EC/KBC) 116, loudspeakers 18A and 18B, etc.

The loudspeakers 18A and 18B output audio sound produced by the computer 10. The sound output from the loudspeakers 18A and 18B has been subjected to a process by a control application 30, which will be described later, in which the volume at a frequency adversely affecting the performance of the HDD 111 is limited.

The CPU 101 is a processor which controls the operation of the computer 10 and it executes the operating system, the control application 30 which controls the reproduction of sound from the computer 10, and the like, loaded to the main memory 103 from the hard disk drive (HDD) 111. Further, the CPU 101 executes Basic Input Output System (BIOS) stored in the BOIS-ROM 109. BIOS is a program for controlling the hardware.

The north bridge 102 is a bridge device which connects between a local bus of the CPU 101 and the south bridge 104. The north bridge 102 also contains a built-in memory controller which controls the access of the main memory 103. Further, the north bridge 102 also has a function of executing communications with the GPU 105 via, for example, a serial bus of PCI Express.

The GPU 105 is a display controller which controls the LCD 17 used as the display monitor of the computer 10. The GPU 105 generates a display signal and sends it to the LCD 17.

The south bridge 104 controls each device on a low pin count (LPC) buss and each device on a peripheral component interconnect (PCI) buss. The south bridge 104 also contains a built-in integrated drive electronics (IDE) controller which controls the HDD 111.

The embedded controller/keyboard controller IC (EC/KBC) 116 is a one-chip microcomputer in which an embedded controller for managing the power and a keyboard controller for controlling the keyboard (KB) 13 and touch pad (16) are integrated. The embedded controller/keyboard controller IC (EC/KBC) 116 has a function of turning ON/OFF the power of the computer 10 in accordance with the user's manipulation of the power button 14.

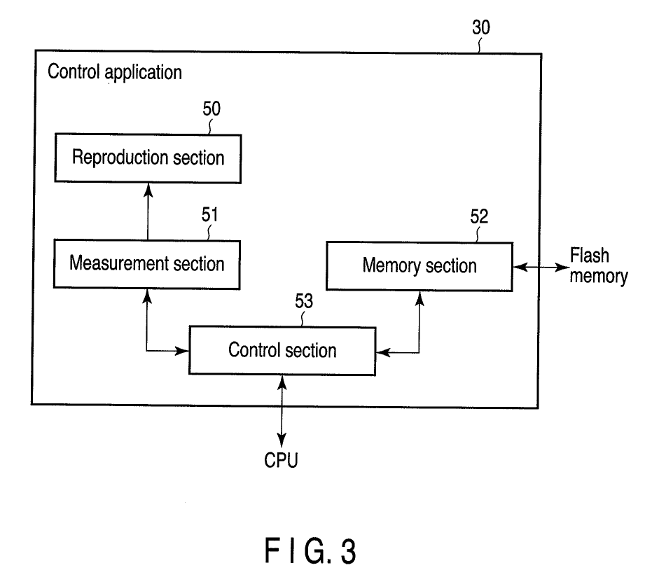

Next, the functional configuration of the control application 30 will now be described with reference to FIG. 3.

The control application 30 comprises a reproduction section 50, a measurement section 51, a control section 53 and a memory section 52. The measurement section 51 measures the performance of the HDD 111. More specifically, audio data are reproduced by the reproduction section 50 from the loudspeakers 18A and 18B with a maximum volume being set in advance at a predetermined volume of sound generated therefrom, and the performance of the HDD 111 at each respective predetermined frequency is measured. In the case where the degradation of the performance of the HDD 111 is monitored, the frequency is stored in the memory section 52, or the flash memory 110, and the frequency of sound to be generated next is increased by a certain frequency range. When the degradation of the performance of the HDD 111 is not detected (when less than a predetermined threshold value), the volume is turned down from the maximum volume by a certain amount. Then the frequency is raised gradually, and when the volume corresponding to the maximum frequency predetermined is stored, the measurement is finished. Here, it is alternatively possible that the measurement starts from the highest frequency and it is finished when the lowest frequency is measured.

Under the control of the CPU 101, the control section 53 controls the loudspeakers 18A and 18B to reproduce sound in accordance with the stored frequency and the volume corresponding to the frequency.

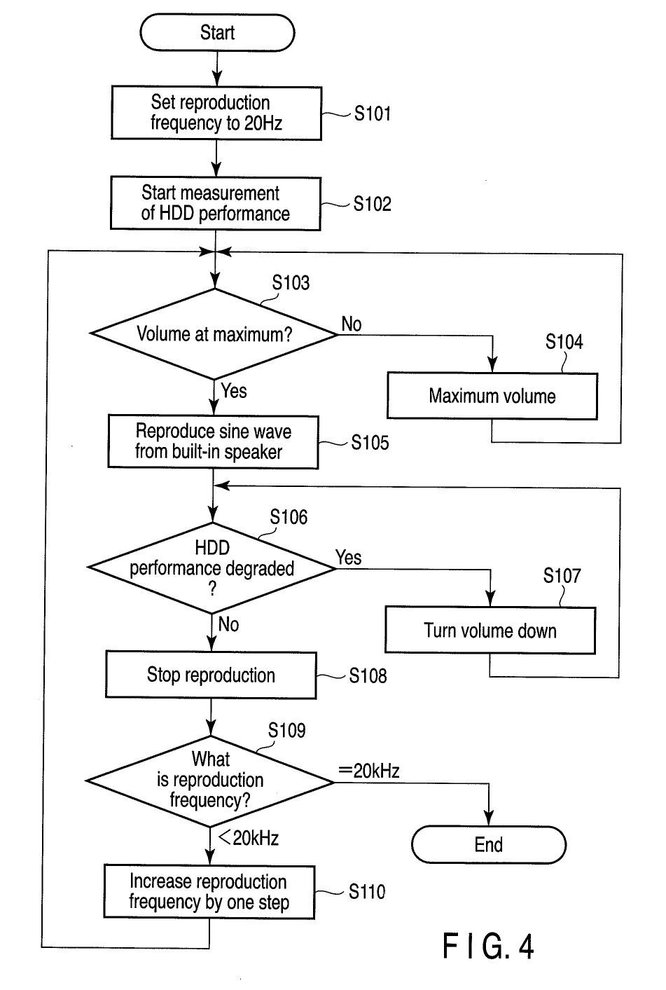

Next, a control method to which a data processing apparatus of the embodiment of the present invention is applied will now be described with reference to a flowchart illustrated in FIG. 4.

Here, the frequency of the reproduced sound to be measured is set to an audio band, for example, from 20 Hz (which is defined as the lowest frequency) to 20 kHz (which is defined as the highest frequency).

The control application 30 sets the frequency of the sound to be reproduced from the loudspeakers 18A and 18B to 20 Hz (Block S101), and the measurement of the performance of the HDD 111 is started (Block S102).

Here, in the case where the volume of the sound reproduced from the loudspeakers 18A and 18B is not at the maximum (No in Block S103), the control application 30 increases the volume to the maximum (Block S104). On the other hand, in the case where the volume of the sound reproduced from the loudspeakers 18A and 18B by the control application 30 is at the maximum (Yes in Block S103), sound of sine wave is reproduced from the built-in loudspeakers 18A and 18B (Block S105). In this embodiment, the sine wave is used for the measurement, but the present invention is not limited to use of sine wave.

Then, the control application 30 judges if the performance of the HDD 111 is not deteriorated due to the vibration of the sound reproduced from the loudspeakers 18A and 18B (if the vibration of the sound is not causing an adverse effect on the HDD 111) (Block S106). In the case where it is judged by the control application 30 that the performance of the HDD 111 has been deteriorated due to the vibration of the sound reproduced from the loudspeakers 18A and 18B (Yes in Block S106), the volume control setting of the computer 10 is adjusted to decrease by 1 unit to turn down the volume (Block S107). For example, the 10-step volume control, which is set to the maximum volume level of 10, is turned down by 1 step, to a volume of 9. On the other hand, in the case where it is judged by the control application 30 that the performance of the HDD 111 has not been deteriorated despite the vibration of the sound reproduced from the loudspeakers 18A and 18B (No in Block S106), the frequency (20 Hz in this case) and the volume corresponding to the frequency (for example, 10 in this case) are stored in the HDD 111 while associating them with each other, and then the reproduction of the sound is stopped (Block S108). In the measurement of the degradation of the performance of the HDD 111, data indicating, for example, the data transfer rate of the HDD 111 (if it has been lowered) or error count (if the number of errors has increased) are referred to in order to judge whether or not the performance of the HDD 11 has been degraded.

Further, in the measurement of the performance of the HDD 111 as to whether it has been degraded, a predetermined identical process is carried out on the HDD 111 for each measurement, the performance is measured during each process.

Next, in the case where the frequency of the reproduced sound is not the highest (<20 kHz in Block S109), the frequency of the reproduced sound is increased from 20 Hz, for example, by one zone to 25 Hz (Block S110). It should be noted that the number of zones divided within the frequency band from, for example, 20 Hz (the lowest frequency) to 20 kHz (the highest frequency) is not particularly limited, but in this embodiment, the frequency band is divided by every 5 Hz, for example.

As described above, the frequency is increased gradually by, for example, 5 Hz, the maximum volume at which the performance of the HDD 111 is not degraded is measured for each frequency up to, for example, 20 kHz, and the thus obtained maximum voltages are stored in the HDD 111 or the like. It should be noted that in this embodiment, the measurements are carried out while the frequency is changed from the lowest one to the highest one, but the present invention is not limited to this. More specifically, the measurements are carried out while the frequency is changed from the highest one to the lowest one.

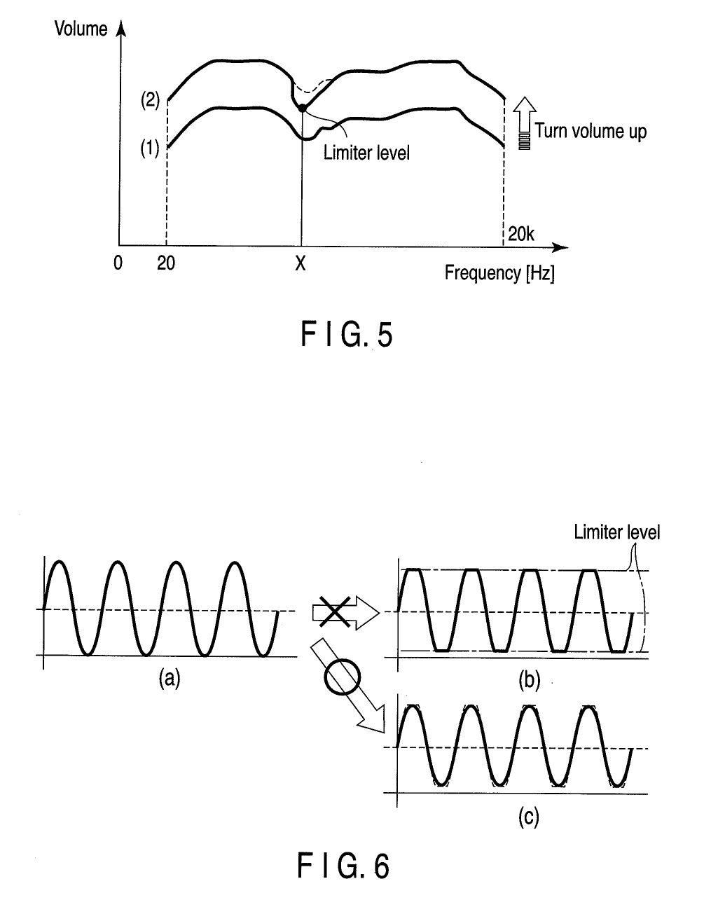

When the measurement is finished, the stored frequency and the volume corresponding to this frequency are plotted in a graph, and, for example, results such as shown in FIG. 5 can be obtained. As shown in FIG. 5, the results of the measurements are indicated by graph (2), whereas graph (1) indicates the cases where the volumes are not at the respective maximum levels (for example, a volume level of 5). Here, if the volume of the loudspeakers 18A and 18B is turned up to the maximum level (for example, a level of 10) in this states, the performance of the HDD 111 is degraded. Then, the sound is produced based on the control of the “measured frequency and the volume corresponding to the frequency”, and the results indicated by graph (2) can be obtained. In graph (2), the volume is not at the maximum around the frequency X [Hz], for example, and thus the volume is limited (limiter level). In this manner, the performance of the HDD 111 is measured as to if it has been degraded, the volume of the sound can be controlled to lower at such a frequency that causes the degradation in the performance of the HDD 111. Further, the volume limiter level is set. That is, as shown in FIG. 6, the limiter level is set (FIG. 6(c)) for the volume of each frequency point which deteriorates the performance of the HDD 111 from the amplitude before the control (FIG. 6(a)) based on the above-described measurement results. Here, such a control method that the output of sound is clipped at the limiter level (FIG. 6(b)) should not be employed (since the top and bottom of the amplitude is cut, thereby making the sound unnatural), but the gain is controlled to reproduce the sound whose output is not clipped. That is, it should be controlled so that the amplitude of the sound stays within the top and bottom of the sound at the maximum volume.

With the control carried out above, the limiter level at a frequency X [Hz] is set at a certain level. When the sound is turned up from a volume lower than the limiter level to the maximum volume, the output of the sound at the frequency X is controlled to be held at the limiter level. (See FIG. 5 and FIG. 6(b).)

As described above, according to the embodiment, only the volume of the sound at the frequency which causes the degradation in the performance of the HDD is lowered, and thus the degradation of the performance of the HDD is prevented. At the same time, the gain is controlled to carry out the control which does not clip the output (that is, the amplitude of the sound is converted to that of the limiter level based on the volume at the frequency X [Hz]), and thus the influence on the audio characteristics can be minimized and thus a natural sound can be reproduced.

The present invention has been proposed as a solution to the above-described drawback of the conventional technique, and an object thereof is to provide a data processing apparatus which can reduce the adverse effect on the audibility of the user when the volume is controlled, and its controlling method.

It should be noted that the present invention is not limited to the above-described embodiments as they are, and when practicing the invention, it can be embodied while the structural elements are modified as long as the essence of the invention remains within the scope thereof. Further, various modified versions of the invention can be formed by combining some of the structural elements disclosed in the above embodiments as needed. For example, some of the structural elements may be deleted from the entire structure presented in the embodiment. Further, structural elements of difference embodiments may be combined as needed.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A data processing apparatus equipped with a memory device and a loudspeaker, the apparatus comprising:
an audio output module configured to generate sound from the loudspeaker;
a measurement module configured to measure a performance of the memory device; and
a controller configured to store a frequency associated to a volume of a sound generated and to increase the frequency of the sound from a first threshold frequency by a first frequency when the performance of the memory device is at or above a threshold level, configured to decrease the volume of the sound from a first threshold volume by a first volume level when the performance of the memory device is at a lower level than the threshold level, configured to finish the measurement when the volume which corresponds to a second threshold frequency is stored, and configured to generate the sound of each frequency between the first threshold frequency and the second threshold frequency from the loudspeaker in accordance with the stored volume corresponding to each frequency.

2. A data processing apparatus equipped with a memory device and a loudspeaker, the apparatus comprising:
an audio output module configured to generate sound from the loudspeaker;
a measurement module configured to measure a performance of the memory device; and
a controller configured to store a frequency associated to a volume of a sound generated and to decrease the frequency of the sound from a first threshold frequency by a first frequency when the performance of the memory device is at or above a threshold value, configured to decrease the volume of the sound from a first volume by a first volume level when the performance of the memory device is at a lower level than the threshold level, configured to finish the measurement when the volume corresponding to a second threshold frequency is stored, and configured to generate the sound of each frequency between the first threshold frequency and the second threshold frequency from the loudspeaker in accordance with the stored volume corresponding to each frequency.

3. The data processing apparatus of claim 1, wherein the sound is generated from the loudspeaker after converting an amplitude of the sound from an amplitude with an upper limit of the first threshold volume into an amplitude with an upper limit set lower than the first threshold volume when the stored volume which corresponds to each frequency is lower than the first threshold volume.

4. The data processing apparatus of claim 2, wherein the sound is generated from the loudspeaker after converting an amplitude of the sound from an amplitude with an upper limit of the first threshold volume into an amplitude with an upper limit set lower than the first threshold volume when the stored volume which corresponds to each frequency is lower than the first threshold volume.

5. The data processing apparatus of claim 1, wherein a sine wave is generated from the loudspeaker when the performance of the recording apparatus is measured.

6. The data processing apparatus of claim 2, wherein a sine wave is generated from the loudspeaker when the performance of the recording apparatus is measured.

7. The data processing apparatus of claim 1, wherein the performance of the memory device is measured using at least one of a transfer speed and an error count.

8. The data processing apparatus of claim 2, wherein the performance of the memory device is measured using at least one of a transfer speed and an error count.

9. A method of controlling a data processing apparatus equipped with a memory device and a loudspeaker, the method comprising:
generating sound from the loudspeaker at a first threshold volume and a first threshold frequency;
measuring a performance of the memory device;
storing a frequency associated to a volume of a sound generated and increasing a frequency of the sound by a first frequency when the performance of the memory device is at or above a threshold value;
decreasing the volume of the sound by a first volume level from the first threshold volume when the performance of the memory device is at a lower level than the threshold level;
finishing the measurement when the volume which corresponds to a second threshold frequency is stored; and
generating the sound between the first threshold frequency and the second threshold frequency from the loudspeaker in accordance with the stored volume corresponding to each frequency.

10. A method of controlling a data processing apparatus equipped with a memory device and a loudspeaker, the method comprising:
generating sound from the loudspeaker at a first threshold volume and a first threshold frequency;
measuring a performance of the memory device;
storing a frequency associated to a volume of the sound generated and decreasing a frequency of the sound by a first frequency when the performance of the memory device is at or above a threshold value;
decreasing the volume of the sound by a first volume level from the first threshold volume when the performance of the memory device is at a lower level than the threshold level;
finishing the measurement when the volume which corresponds to a second threshold frequency is stored; and
generating the sound between the first threshold frequency and the second threshold frequency from the loudspeaker in accordance with the stored volume corresponding to each frequency.

11. The controlling method of claim 9, wherein the sound is generated from the loudspeaker after converting an amplitude of the sound from an amplitude with an upper limit of the first threshold volume into an amplitude with an upper limit set lower than the first threshold volume when the stored volume which corresponds to each frequency is lower than the first threshold volume.

12. The controlling method of claim 10, wherein the sound is generated from the loudspeaker after converting an amplitude of the sound from an amplitude with an upper limit of the first threshold volume into an amplitude with an upper limit set lower than the first threshold volume when the stored volume which corresponds to each frequency is lower than the first threshold volume.

13. The controlling method of claim 9, wherein a sine wave is generated from the loudspeaker when the performance of the recording apparatus is measured.

14. The controlling method of claim 10, wherein a sine wave is generated from the loudspeaker when the performance of the recording apparatus is measured.

15. The controlling method of claim 9, further comprising:
measuring the performance of the memory device by at least one of a transfer speed and an error count.

16. The controlling method of claim 10, further comprising:
measuring the performance of the memory device by at least one of a transfer speed and an error count.
